(19) United States
(12) Patent Application Publication
(10) Pub. No.: US 2026/0293700 A1
(43) Pub. Date: Sep. 24, 2026

(54) SEMICONDUCTOR PACKAGE

(71) Applicant: LG INNOTEK CO., LTD., Seoul (KR)

(72) Inventors: Dae Hyeon SEONG, Seoul (KR); Su Jin PARK, Seoul (KR); Dong Hyuk KOH, Seoul (KR)

(21) Appl. No.: 18/868,813

(22) PCT Filed: May 23, 2023
(86) PCT No.: PCT/KR2023/007026

§ 371 Date: Nov. 25, 2024

(30) Foreign Application Priority Data
May 23, 2022 (KR) 10-2022-0062618

(51) Int. Cl. H10W 70/00; H10W 70/05; H10W 70/63; H10W 70/652; H10W 70/685; H10W 74/10; H10W 90/00

(52) U.S. Cl. CPC H10W 70/099; H10W 70/093; H10W 70/095; H10W 70/635; H10W 70/652; H10W 70/687; H10W 74/117; H10W 90/401; H10W 90/724

(57) ABSTRACT

A semiconductor package according to an embodiment includes an insulating layer; a protective layer disposed on the insulating layer; a through electrode passing through the insulating layer; and a bump part disposed on the through electrode and passing through the protective layer, wherein the bump part includes a first portion connected to the through electrode; and a second portion disposed on the first portion and protruding onto the protective layer, and a width of the first portion in a horizontal direction is same as a width of the second portion in the horizontal direction.

### TECHNICAL FIELD

An embodiment relates to a circuit board and a semiconductor package including the same.

### background Art

A semiconductor package has a structure in which a semiconductor chip is attached to a circuit board. A semiconductor package can be provided by integrating multiple packages with different devices attached into one. Since multiple components are implemented in one package, such a semiconductor package has the advantage of being able to transmit high-speed signals through a short path. Accordingly, the semiconductor packages are widely used in a mobile device, etc.

Meanwhile, when attaching electronic devices such as semiconductor chips to a circuit board, the semiconductor package is performed by applying a wire. The semiconductor package with the wire structure has a problem of increasing volume. Accordingly, semiconductor packages are recently being performed by flip chip packaging. Flip chip packaging is a method of bonding and packaging semiconductor chips and circuit boards by fusing solder bumps to the connection patterns of semiconductor chips or circuit boards without using additional connecting materials such as wires when attaching electronic components such as semiconductor chips to a circuit board.

Recently, a bump pitch of an electronic device is becoming smaller due to a demand for high-speed, large-capacity data processing and the miniaturization of electronic products. Following this trend, reliability of a bump connection between the circuit board and the semiconductor chip is decreasing in flip chip packaging. In order to prevent this decrease in reliability, Korean Patent Publication No. 10-2013-0027870 proposes a structure including a bump part with improved reliability.

### DISCLOSURE

### Technical Problem

The embodiment provides a circuit board having a novel structure and a semiconductor package including the same.

In addition, the embodiment provides a circuit board capable of reducing a pitch between a plurality of bump parts and a semiconductor package including the same.

In addition, the embodiment provides a circuit board capable of improving a circuit integration degree and a semiconductor package including the same.

In addition, the embodiment provides a circuit board having improved connection reliability between a pad portion and a bump portion of a bump part and a semiconductor package including the same.

In addition, the embodiment provides a circuit board capable of minimizing a degree of a recess portion formed at a side surface of a lower region of a bump part and a semiconductor package including the same.

In addition, the embodiment provides a circuit board capable of minimizing a thickness deviation of a plurality of bump parts and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment includes an insulating layer; a protective layer disposed on the insulating layer; a through electrode passing through the insulating layer; and a bump part disposed on the through electrode and passing through the protective layer, wherein the bump part includes a first portion connected to the through electrode; and a second portion disposed on the first portion and protruding onto the protective layer, and wherein a width of the first portion in a horizontal direction is same as a width of the second portion in the horizontal direction.

In addition, the width of the first portion in the horizontal direction is greater than a width of an upper surface of the through electrode.

In addition, the first portion and the second portion of the bump part are formed integrally.

In addition, the first portion and the second portion of the bump part are formed integrally with the through electrode.

In addition, the bump part includes a plurality of metal layers, and a width of at least one of the plurality of metal layers is different from a width of at least another one of the plurality of metal layers.

In addition, the plurality of metal layers include: a first metal layer disposed on the insulating layer, a second metal layer disposed on the first metal layer; and a third metal layer disposed on the second metal layer, wherein a width of the first metal layer is smaller than a width of the third metal layer.

In addition, a width of the second metal layer is greater than the width of the first metal layer.

In addition, the width of the third metal layer is greater than a width of the second metal layer.

In addition, the first metal layer is a chemical copper plating layer, wherein the second metal layer is a first electrolytic plating layer, and the third metal layer is a second electrolytic plating layer.

In addition, the bump part further includes a fourth metal layer provided between the insulating layer and the first metal layer, and the width of the third metal layer is greater than a width of the fourth metal layer.

In addition, the fourth metal layer is a copper layer.

In addition, the first metal layer has a first thickness in a range of 0.5 um to 1.5 um, the second metal layer has a second thickness in a range of 3 um to 5 um, the third metal layer has a third thickness in a range of 100 um to 220 um, and the fourth metal layer has a fourth thickness in a range of 0.8 um to 2 um.

In addition, the semiconductor package further includes a pad part disposed on the insulating layer and spaced from the bump part in the horizontal direction, and the pad part overlaps the first portion of the bump part in the horizontal direction.

In addition, the pad part includes first to third metal layers corresponding to the first to third metal layers of the bump part.

In addition, a thickness of the third metal layer of the pad part is smaller than the thickness of the third metal layer of the bump part.

In addition, the semiconductor package further includes a trace disposed on the insulating layer and spaced apart from the bump part in a horizontal direction, and the trace overlaps the first portion of the bump part in a horizontal direction.

In addition, the trace includes first to third metal layers corresponding to the first to third metal layers of the bump part.

In addition, a thickness of the third metal layer of the trace is smaller than the thickness of the third metal layer of the bump part.

### Advantageous Effects

The circuit board of the embodiment comprises an insulating layer, a through electrode passing through the insulating layer, and a first circuit layer disposed on the insulating layer. At this time, the first circuit layer includes a bump part. The bump part is provided to pass through a protective layer disposed on the insulating layer and protrude on the protective layer.

The bump part includes a first portion disposed on the insulating layer and the through electrode, and a second portion on the first portion. There is no interface between the first portion and the second portion of the bump part. In other words, the first portion and the second portion are formed integrally with each other. Furthermore, the through electrode is formed integrally with the first portion and the second portion of the bump part. In other words, there is no interface between the through electrode and the bump part.

Therefore, the bump part of the embodiment does not have an additional layer disposed between the first portion and the second portion. Specifically, the bump part does not have a seed layer between the first portion and the second portion. Through this, the embodiment can improve physical connectivity and electrical connectivity between the first portion and the second portion of the bump part. Furthermore, the bump part of the embodiment is formed integrally with the through electrode, and thus the electrical and physical reliability can be further improved.

At this time, in a comparative example, the pad part and the bump part are formed through separate plating processes separated from each other. Therefore, the comparative example has problems in that the electrical and physical connectivity between them is reduced and the signal transmission loss is increased. Furthermore, the comparative example has a structure in which a seed layer is additionally disposed between the pad part and the bump part, and thus overall reliability of the bump part is reduced due to physical reliability problem of the seed layer.

In contrast, the embodiment has a structure in which the through electrode, the first portion of the bump part, and the second portion of the bump part are formed integrally with each other. Accordingly, the embodiment can improve the electrical and physical connectivity between the through electrode and the bump part. Accordingly, the embodiment can improve the physical reliability and electrical reliability of the circuit board.

In addition, the bump part of the embodiment includes a first metal layer, a second metal layer, and a third metal layer. In addition, the second metal layer is a first electroplated layer in which the first metal layer is electroplated as a seed layer, and the third metal layer is a second electroplated layer in which the first metal layer and the second metal layer are electroplated as seed layers.

Therefore, the embodiment can minimize a depth of a recess portion that occurs in an etching process of the seed layer that is performed after a formation of the circuit layer. That is, the second metal layer can have a higher strength than the first metal layer as an electroplated layer. Therefore, the second metal layer can function as a barrier layer that minimizes the depth of the recess portion that occurs at a side surface of the first metal layer in the etching process. Furthermore, the second metal layer can function to prevent the third metal layer from being deformed in the etching process. Therefore, the embodiment can minimize a depth of a recess portion formed at a lower side surface of the bump part by the bump part further including the second metal layer. Therefore, the embodiment can improve the physical reliability and electrical reliability of the bump part.

In addition, the third metal layer of the bump part is electroplated not only on the first metal layer but also on the second metal layer as a seed layer. Accordingly, the embodiment can minimize a thickness deviation between the plurality of bump parts included in the circuit board.

Specifically, in the circuit board of the comparative example, the plating of the bump part is performed using only the chemical copper plating layer as the seed layer. At this time, the bump part has a thickness of 100 um or more. Accordingly, when plating a metal layer having a thickness of 100 um or more, it is difficult to perform a plating process having a uniform thickness over an entire region with only the chemical copper plating layer. Therefore, in the circuit board of the comparative example, the thickness deviation of each bump part exceeded 30% compared to an average value of a thickness of the plurality of bump parts. For example, when the average value was 100 um, the thickness of at least one bump part among the plurality of bump parts was less than 70 um or exceeded 130 um. Accordingly, in the circuit board of the comparative example, the plating process is performed so that a thickness of each bump part is greater than a target thickness in order to match the thickness of each bump part. Accordingly, the comparative example had a problem that a polishing process must be included to uniformize the thickness while finally adjusting the thickness of the bump part to the target thickness, and the polishing process time increases.

In contrast, the embodiment performs electrolytic plating of the third metal layer of the bump part using not only the first metal layer of the bump part but also the second metal layer as a seed layer. Accordingly, the embodiment can minimize the thickness deviation between a plurality of bump parts. Accordingly, the embodiment can perform a plating process under a condition that the bump part has a thickness corresponding to a target thickness. Accordingly, the embodiment can omit the polishing process or drastically shorten the polishing process time.

### DESCRIPTION OF DRAWINGS

FIG. 1 is a cross-sectional view showing a circuit board according to a comparative example.

FIG. 2 is a cross-sectional view showing a circuit board according to an embodiment.

FIG. 3 is a cross-sectional view showing a layer structure of a bump part of a first circuit layer of a first embodiment.

FIG. 4 is a cross-sectional view showing a layer structure of a pad of a first circuit layer of a first embodiment.

FIG. 5 is a cross-sectional view showing a layer structure of a trace of a first circuit layer of a first embodiment.

FIG. 6 is a cross-sectional view showing a layer structure of a second circuit layer of an embodiment.

FIG. 7 is a cross-sectional view showing a layer structure of a bump part of a first circuit layer of a second embodiment.

FIG. 8 is an enlarged view showing an enlarged view of region A of FIG. 7 according to a first embodiment.

FIG. 9 is an enlarged view showing an enlarged view of region A of FIG. 7 according to a second embodiment.

FIG. 10 is a drawing showing a semiconductor package according to an embodiment.

FIGS. 11 to 22 are cross-sectional views showing the manufacturing method of the circuit board illustrated in FIG. 2 in order of processes.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

### Comparative Example

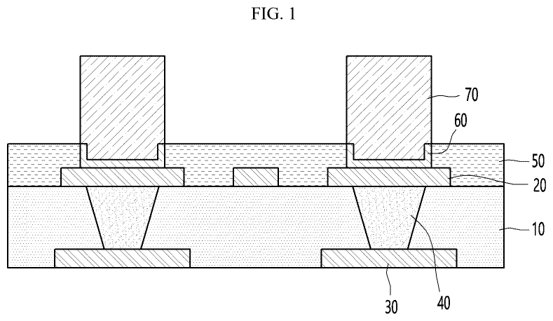

FIG. 1 is a cross-sectional view showing a circuit board according to a comparative example.

Referring to FIG. 1, the circuit board includes an insulating layer 10.

In addition, a first circuit pattern 20 is disposed on an upper surface of the insulating layer 10, and a second circuit pattern 30 is disposed on a lower surface of the insulating layer 10. The first circuit pattern 20 includes a pad.

In addition, the circuit board of the comparative example includes a through electrode passing through the insulating layer 10.

A protective layer 50 is disposed on an upper surface of the insulating layer 10 and having an opening that vertically overlaps with the upper surface of the pad of the first circuit pattern 20.

In addition, a bump 70 is disposed on the pad of the first circuit pattern 20.

The bump 70 has a certain height or thickness and protrudes on the pad of the first circuit pattern 20. Therefore, it is difficult to form the bump 70 by electroless plating.

Accordingly, a seed layer 60 is disposed between the bump 70 and the pad of the first circuit pattern 20. The seed layer 60 is a chemical copper plating layer.

The seed layer 60 is disposed on the upper surface of the pad of the first circuit pattern 20 and an inner wall of the protective layer 50, respectively.

That is, the comparative example has a structure in which the seed layer 60 is disposed between the bump 70 and the pad of the first circuit pattern 20. Accordingly, the comparative example has a problem in that a process of forming the seed layer 60 must be additionally performed, and a manufacturing process becomes complicated or a manufacturing time increases accordingly.

In addition, the circuit board of the comparative example experiences a whitening phenomenon of the protective layer 50 by a solution used in a de-smear process of the seed layer 60 formed by electroless plating. In addition, the circuit board of the comparative example has a structure in which a seed layer 60 is disposed between the pad and the bump 70, and thus the bump layer has a porous microstructure. At this time, the porous structure has a low metal density, and therefore, there is a problem in which cracks occur in the porous seed layer 60 due to external impact or other physical force. In addition, there is a problem in which the bump 70 is destroyed due to the occurrence of the cracks, and thus the product reliability or durability is drastically reduced.

In addition, the comparative example has a problem in which the connection reliability between the pad and the bump 70 is reduced due to the structure in which the seed layer 60 is disposed.

In addition, the comparative example has a problem in which the seed layer 60 is etched in a pretreatment process for surface treatment of the bump 70, and thus the bump 70 does not perform its normal function.

In addition, the bumps 70 of the comparative example are disposed on the pads with a width smaller than a width of the pads. Accordingly, a pitch between the plurality of bumps corresponds to a pitch between the plurality of pads connected to the plurality of bumps. In addition, the pitch between the plurality of pads corresponds to the pitch between the plurality of through electrodes connected thereto.

At this time, the comparative example determines the pitch between the through electrodes, the pitch between the pads, and the pitch between the bumps by considering all of tolerances in a process of forming the bumps 70, the tolerances in the process of forming the pads of the first circuit pattern 20, and the tolerances in the process of forming the through holes of the through electrodes 40. Accordingly, the comparative example has a limitation in reducing the pitch between the plurality of bumps.

In addition, the comparative example performs plating of the bumps 70 by a seed layer 60 separately disposed on the pads of the first circuit pattern 20. Accordingly, the comparative example has a problem of a large thickness deviation between the plurality of bumps 70. Therefore, the comparative example has a problem that a polishing process must be performed to match the thickness of a plurality of bumps.

The embodiment provides a circuit board and a semiconductor package including the same capable of improving circuit integration by reducing a pitch between a plurality of bump parts (posts), improving connection reliability between a pad portion and a bump portion of the bump part, minimizing the degree of denting of a recess portion formed at a side surface of a lower region, and minimizing thickness deviation of a plurality of bump parts.

### Electronic Device

Before describing an embodiment, an electronic device including the semiconductor package of the embodiment will be briefly described. The electronic device includes a main board (not shown). The main board may be physically and/or electrically connected to various components. For example, the main board may be electrically connected to the semiconductor package of the embodiment. Various devices may be mounted on the semiconductor package. The semiconductor package may include various devices or chips. The device or chip may include memory chips such as volatile memory (e.g., DRAM), non-volatile memory (e.g., ROM), and flash memory, application processor chips such as a central processor (e.g., CPU), graphics processor (e.g., GPU), antenna chip, digital signal processor, cryptographic processor, microprocessor, and microcontroller, and logic chips such as analog-digital converters and ASICs (application-specific ICs).

In addition, device or chip may include passive devices and active devices.

The active device refers to a component that actively utilizes a nonlinear portion of the signal characteristics. In addition, the passive device refers to a component that does not utilize the nonlinear signal characteristics even though both linear and nonlinear signal characteristics exist. For example, the active device may include a transistor, an IC semiconductor device, and the passive device may include a capacitor, a resistor, an inductor, and the like. The passive device may increase the signal processing speed of the semiconductor chip, which is the active device, or perform a filtering function. In addition, the chip may be a wireless communication chip that can be used for Wi-Fi or 5G communication.

Meanwhile, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package On Package), and SIP (System In Package), but is not limited thereto.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

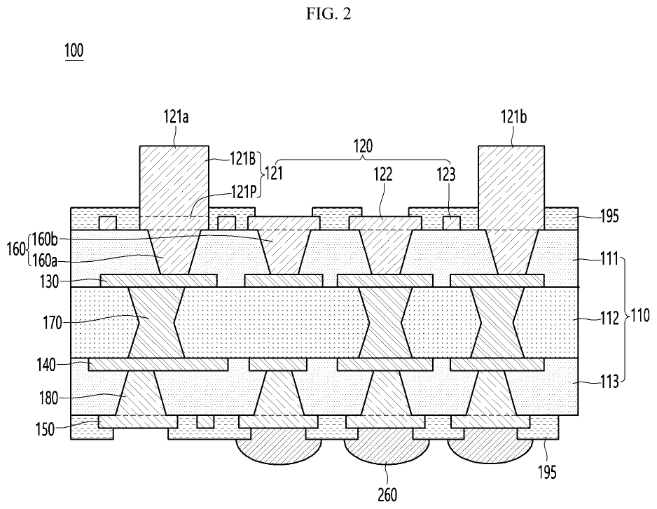

FIG. 2 is a cross-sectional view showing a circuit board according to an embodiment.

Hereinafter, an overall structure of the circuit board according to the embodiment will be described with reference to FIG. 2.

Referring to FIG. 2, the circuit board 100 enables at least one chip to be attached. In addition, the circuit board 100 of the embodiment enables attachment to a main board of an electronic device. The main board may mean a motherboard of an electronic device.

In addition, a number of chips mounted on the circuit board 100 may be one, or alternatively, two or more. For example, one processor chip may be mounted on the circuit board 100. For example, at least two processor chips having different functions may be mounted on the circuit board 100. For example, one memory chip may be mounted together with one processor chip on the circuit board 100. For example, at least two processor chips having different functions and at least one memory chip may be mounted on the circuit board 100.

The circuit board 100 includes an insulating layer 110.

At this time, the circuit board 100 of the embodiment may be a core board. For example, the circuit board 100 may include a second insulating layer 112 of the core layer.

For example, the circuit board 100 may have a structure in which a plurality of insulating layers having mutually symmetrical structures are laminated on upper and lower portions thereof with the second insulating layer 112 as a center. However, the embodiment is not limited thereto. For example, a plurality of insulating layers having mutually asymmetrical structures may be disposed on the upper and lower portions thereof with the second insulating layer 112 as a center.

Hereinafter, the circuit board 100 of the embodiment is described as being a core board, and accordingly, the second insulating layer 112 is a core layer. However, the embodiment is not limited thereto. For example, the circuit board 100 of the embodiment may be a coreless board that does not include a core layer. A structural feature of the circuit board 100 of the embodiment is a circuit layer of an outermost layer of the circuit board 100. Hereinafter, a structure of the circuit layer of the outermost layer of the circuit board 100 of the embodiment will be described.

Accordingly, the structure of the circuit layer 120 of the outermost layer of the circuit board 100 described below may be applied to a core board, and differently, may be applied to a coreless board. Furthermore, the structure of the circuit layer 120 of the outermost layer may be applied not only to the laminated structure of a general circuit board, but also to a circuit board of an ETS (Embedded Trace Substrate) structure.

The circuit board 100 of the embodiment includes an insulating layer 110.

The insulating layer 110 may include a first insulating layer 111, a second insulating layer 112, and a third insulating layer 113 from an upper side.

The second insulating layer 112 may refer to an inner insulating layer disposed on an inner layer among the multiple insulating layers of the circuit board 100. The second insulating layer 112 may include a prepreg.

At this time, although the first insulating layer 111 is illustrated as having a single-layer structure in a drawing, the embodiment is not limited thereto. For example, the first insulating layer 111 may have a multi-layer structure. For example, the circuit board 100 may have a layer structure of four or more layers. In addition, the first insulating layer 111 corresponding to the inner insulating layer of the circuit board 100 may have a multiple-layer structure based on the total number of layers of the circuit board 100.

The first insulating layer 111 may be disposed on the second insulating layer 112. For example, the first insulating layer 111 may be disposed on an upper surface of the second insulating layer 112.

The first insulating layer 111 may refer to a first outermost insulating layer in the insulating layer 110 of the circuit board 100. For example, the first insulating layer 111 may refer to an insulating layer disposed at an uppermost side in the insulating layer 110 of the circuit board 100. The first insulating layer 111 may provide a mounting region where a chip is mounted, or a bonding region where an external substrate, such as a main board of an electronic device, is bonded.

The third insulating layer 113 may be disposed on a lower surface of the second insulating layer 112. The third insulating layer 113 may refer to a second outermost insulating layer in the insulating layer 110 of the circuit board 100. For example, the third insulating layer 113 may refer to an insulating layer disposed at a lowermost side in the insulating layer 110 of the circuit board 100.

The first insulating layer 111 and the third insulating layer 113 may be rigid or flexible. For example, the first insulating layer 111 and the third insulating layer 113 may include glass or plastic. In detail, the first insulating layer 111 and the third insulating layer 113 may include chemically strengthened/semi-strengthened glass such as soda lime glass or aluminosilicate glass. Alternatively, the first insulating layer 111 and the third insulating layer 113 may include a strengthened or flexible plastic such as polyimide (PI), polyethylene terephthalate (PET), propylene glycol (PPG), or polycarbonate (PC). Alternatively, the first insulating layer 111 and the third insulating layer 113 may include sapphire.

In addition, the first insulating layer 111 and the third insulating layer 113 may include an optically isotropic film. For example, the first insulating layer 111 and the third insulating layer 113 may include COC (Cyclic Olefin Copolymer), COP (Cyclic Olefin Polymer), optically isotropic polycarbonate (PC), or optically isotropic polymethylmethacrylate (PMMA).

In addition, the first insulating layer 111 and the third insulating layer 113 may be formed of a material including an inorganic filler and an insulating resin. For example, the first insulating layer 111 and the third insulating layer 113 may include a structure in which an inorganic filler such as silica or alumina is dispersed in a thermosetting resin such as an epoxy resin or a thermoplastic resin such as a polyimide. For example, the first insulating layer 111 and the third insulating layer 113 may include ABF (Ajinomoto Build-up Film), FR-4, BT (Bismaleimide Triazine), PID (Photo Imageable Dielectric resin), BT, etc.

In addition, the first insulating layer 111 and the third insulating layer 113 can be bent while having a partially curved surface. That is, the first insulating layer 111 and the third insulating layer 113 can be bent while having a partially flat surface and a partially curved surface. In detail, the first insulating layer 111 and the third insulating layer 113 can be bent while having a curved surface at an end or can be bent or bent while having a surface including a random curvature.

In addition, the first insulating layer 111 and the third insulating layer 113 can be a flexible substrate having a flexible characteristic. In addition, the first insulating layer 111 and the third insulating layer 113 can be a curved or bent substrate.

Each of the first insulating layer 111 and the third insulating layer 113 can have a thickness in a range of 10 μm to 60 μm. Preferably, each of the first insulating layer 111 and the third insulating layer 113 may have a thickness in a range of 12 um to 50 um. More preferably, each of the first insulating layer 111 and the third insulating layer 113 may have a thickness in a range of 15 um to 40 um.

If the thickness of the first insulating layer 111 or the third insulating layer 113 is less than 10 um, the circuit layer included in the circuit board 100 may not be stably protected.

In addition, if the thickness of the first insulating layer 111 or the third insulating layer 113 exceeds 60 um, a thickness of the circuit board 100 may increase, thereby increasing a thickness of the semiconductor package. In addition, if the thickness of the first insulating layer 111 or the third insulating layer 113 exceeds 60 um, a thickness of the circuit layer and a thickness of the through electrode may increase correspondingly. In addition, if the thickness of the circuit layer and the thickness of the through electrode increase, it is difficult to implement miniaturization, so the circuit integration may decrease, and the signal transmission distance may increase, so that the signal transmission loss may increase.

The circuit board 100 of the embodiment includes a circuit layer disposed on an insulating layer 110.

For example, the circuit board 100 may include a first circuit layer 120 disposed on an upper surface of a first insulating layer 111.

For example, the circuit board 100 may include a second circuit layer 130 disposed between a lower surface of the first insulating layer 111 and an upper surface of a second insulating layer 112.

For example, the circuit board 100 may include a third circuit layer 140 disposed between a lower surface of the second insulating layer 112 and an upper surface of a third insulating layer 113.

For example, the circuit board 100 may include a fourth circuit layer 150 disposed on the lower surface of the third insulating layer 113.

The first circuit layer 120, the second circuit layer 130, the third circuit layer 140, and the fourth circuit layer 150 may be manufactured using conventional printed circuit board manufacturing processes such as an additive process, a subtractive process, a modified semi-additive process (MSAP), and a semi-additive process (SAP), and a detailed description thereof is omitted herein.

The first circuit layer 120 may refer to a circuit layer disposed on the first outermost layer of the circuit board 100. In addition, the fourth circuit layer 140 may refer to a circuit layer disposed on the second outermost layer of the circuit board 100.

The first circuit layer 120 may have a structure that protrudes above the upper surface of the first insulating layer 111. In addition, the fourth circuit layer 140 may have a structure protruding below the lower surface of the third insulating layer 113. However, the embodiment is not limited thereto. For example, if the circuit board 100 of the embodiment has an ETS structure, one of the first circuit layer 120 and the fourth circuit layer 140 (preferably, the fourth circuit layer) may have a structure embedded in a surface of the insulating layer.

The first circuit layer 120 may be divided into a plurality of circuit patterns according to function.

For example, the first circuit layer 120 may include a first circuit pattern 121, a second circuit pattern 122, and a third circuit pattern 123.

The first circuit pattern 121 functions as a metal bump part for bonding an external substrate (e.g., a main board of an electronic device) on the circuit board 100. Accordingly, the first circuit pattern 121 may also be referred to as a ‘bump part’. Hereinafter, the first circuit pattern 121 is described as a ‘bump part’.

The second circuit pattern 122 functions as a mounting pad for mounting a chip on a circuit board 100. Accordingly, the second circuit pattern 122 may also be referred to as a ‘pad’. Hereinafter, the second circuit pattern 122 is described as a ‘pad’.

The third circuit pattern 123 functions as a trace that is connected to at least one of the first circuit pattern 121 and the second circuit pattern 122 and performs a wiring function. Accordingly, the third circuit pattern 123 may also be referred to as a ‘trace’. Hereinafter, the third circuit pattern 123 is described as a ‘trace’.

The bump part 121 may have a different thickness from the pad 122 and the trace 123. Preferably, the bump part 121 may have a thickness greater than the thickness of the pad 122 and the trace 123. In addition, the pad 122 and the trace 123 may have the same thickness. Here, the same thickness may mean that a thickness difference between the pad 122 and the trace 123 is 5 um or less, 4 um or less, 3 um or less, 2 um or less, or 1 um or less.

The thickness of the bump part 121 may be 3 times or more the thickness of the pad 122 or the trace 123. For example, the thickness of the bump part 121 may be 5 times or more the thickness of the pad 122 or the trace 123. For example, the thickness of the bump part 121 may be 7 times or more the thickness of the pad 122 or the trace 123. For example, the thickness of the bump part 121 may be 10 times or more the thickness of the pad 122 or the trace 123.

At this time, a fact that the thickness of the bump part 121 is greater than the thickness of the pad 122 or the thickness of the trace 123 does not mean that a number of layers of the metal layer constituting the bump part 121 is greater than a number of layers of the metal layer constituting the pad 122 or the trace 123. In other words, a number of layers of the metal layer constituting the bump part 121 is the same as a number of layers of the metal layer constituting the pad 122 or the trace 123. In other words, the layer structure of the bump part 121 is the same as the layer structure of the pad 122 or the trace 123. However, a thickness of any one of the metal layers constituting the bump part 121 is greater than a thickness of a corresponding metal layer of the pad 122 or the trace 123.

Accordingly, the thickness of the bump part 121 is greater than the thickness of the pad 122 or the trace 123.

The bump part 121 can be divided into a plurality of portions. The bump part 121 can be divided into a first portion 121P and a second portion 121B based on a thickness direction. At this time, the division of the first portion 121P and the second portion 121B does not mean a layer division. Specifically, the first portion 121P and the second portion 121B are a single configuration formed integrally with each other, and may be divided only based on the pad 122 or the trace 123.

The first portion 121P of the bump part 121 may mean a pad portion of the bump part 121. The first portion 121P of the bump part 121 may have a thickness corresponding to the thickness of the pad 122 or the trace 123.

The second portion 121B of the bump part 121 is disposed on the first portion 121P of the bump part 121. The second portion 121B of the bump part 121 may be referred to as a bump portion of the bump part 121.

Accordingly, the bump part 121 may be greater than the thickness of the pad 122 or the trace 123 by a thickness of the second portion 121B.

To this end, the bump part 121 may be formed through a separate plating process from the pad 122 or the trace 123. However, the embodiment is not limited thereto. The first portion 121P of the bump part 121 may be formed in the plating process of the pad 122 or the trace 123, and the second portion 121B of the bump part 121 may be formed as one with the first portion 121P by performing an additional plating process.

Through this, the bump part 121 of the embodiment does not have an additional layer disposed between the first portion 121P and the second portion 121B. Specifically, the bump part 121 does not have a seed layer between the first portion 121P and the second portion 121B. Through this, the embodiment can improve the physical connectivity and electrical connectivity between the first portion 121P and the second portion 121B of the bump part 121. In addition, widths of the first portion 121P and the second portion 121B of the bump part 121 can correspond to each other. Here, the width of the first portion 121P may mean a width at a position that does not horizontally overlap with a recess portion (121U of FIG. 22) included in a lower region of the first portion 121P. Accordingly, the embodiment can determine a pitch between a plurality of bump parts 121a and 121b based on a pitch of the second portion 121B of the bump part 121.

The detailed structures of the bump part 121, pad 122, and trace 123 of the first circuit layer 120 are described in more detail below.

The second circuit layer 130, the third circuit layer 140, and the fourth circuit layer 150 may have different layer structures from the first circuit layer 120. For example, the number of layers of the metal layers of the second circuit layer 130, the third circuit layer 140, and the fourth circuit layer 150 may be different from the number of layers of the metal layers of the first circuit layer 120. For example, the number of layers of the metal layers of the second circuit layer 130, the third circuit layer 140, and the fourth circuit layer 150 may be smaller than the number of layers of the metal layers of the first circuit layer 120.

Specifically, the first circuit layer 120, the second circuit layer 130, the third circuit layer 140, and the fourth circuit layer 150 each include a metal layer corresponding to a seed layer. In addition, a layer number of the seed layers of the second circuit layer 130, the third circuit layer 140, and the fourth circuit layer 150 may be smaller than a layer number of the seed layer of the first circuit layer 120.

However, the fourth circuit layer 150 is a second outermost circuit layer of the circuit board, and may be formed together with the first circuit layer 120. Accordingly, in order to improve processability, the embodiment may allow the fourth circuit layer 150 to have a layer structure corresponding to the first circuit layer 120.

The first circuit layer 120, the second circuit layer 130, the third circuit layer 140, and the fourth circuit layer 150 may be formed of at least one metal material selected from gold (Au), silver (Ag), platinum (Pt), titanium (Ti), tin (Sn), copper (Cu), and zinc (Zn). In addition, the first circuit layer 120, the second circuit layer 130, the third circuit layer 140, and the fourth circuit layer 150 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit layer 120, the second circuit layer 130, the third circuit layer 140, and the fourth circuit layer 150 may be formed of copper (Cu) which is relatively inexpensive.

The second circuit layer 130, the third circuit layer 140, and the fourth circuit layer 150 may have a thickness in a range of 5 um to 20 um. For example, the second circuit layer 130, the third circuit layer 140, and the fourth circuit layer 150 may have a thickness in a range of 6 um to 17 um. The second circuit layer 130, the third circuit layer 140, and the fourth circuit layer 150 may have a thickness in a range of 7 um to 13 um. When the thickness of the second circuit layer 130, the third circuit layer 140, and the fourth circuit layer 150 is less than 5 um, the resistance may increase. When the thickness of the second circuit layer 130, the third circuit layer 140, and the fourth circuit layer 150 exceeds 20 um, circuit miniaturization may be difficult, and thus the circuit integration may decrease.

Meanwhile, the pad 122 and trace 123 of the first circuit layer 120 may have a thickness corresponding to the thickness of the second circuit layer 130, the third circuit layer 140, and the fourth circuit layer 150.

In addition, a thickness of the bump part 121 of the first circuit layer 120 may be larger than the thickness of the pad 122, the trace 123, the second circuit layer 130, the third circuit layer 140, and the fourth circuit layer 150.

The thickness of the bump part 121 of the first circuit layer 120 may exceed 100 um. The thickness of the bump part 121 of the first circuit layer 120 may exceed 120 um. The thickness of the bump part 121 of the first circuit layer 120 may exceed 140 um. The thickness of the bump part 121 of the first circuit layer 120 may exceed 160 um. The thickness of the bump part 121 of the first circuit layer 120 may exceed 200 um.

The thickness of the bump part 121 of the first circuit layer 120 may satisfy a range of 100 um to 220 um. Preferably, the thickness of the bump part 121 of the first circuit layer 120 may satisfy a range of 110 um to 215 um. More preferably, the thickness of the bump part 121 of the first circuit layer 120 may satisfy a range of 115 um to 210 um.

If the thickness of the bump part 121 of the first circuit layer 120 is less than 100 um, an external substrate (e.g., a main board of an electronic device) may not be stably bonded to the first bump part 121. For example, if the thickness of the bump part 121 of the first circuit layer 120 exceeds 220 um, the rigidity of the bump part 121 may be reduced, and thus, reliability problems such as collapse when the external substrate is bonded may occur. In addition, if the thickness of the bump part 121 of the first circuit layer 120 exceeds 220 um, the thickness deviation between the plurality of bump parts may increase, and thus, a time for the polishing process may increase. In addition, if the thickness of the bump part 121 of the first circuit layer 120 exceeds 220 um, the thickness of the circuit board 100 and the thickness of the semiconductor package may increase.

The circuit board of the embodiment may include a through electrode.

Specifically, the through electrode may pass through the insulating layer 110. Preferably, the through electrode includes a first through electrode 160 passing through the first insulating layer 111. In addition, the through electrode includes a second through electrode 170 passing through the second insulating layer 112. In addition, the through electrode includes a third through electrode 180 passing through the third insulating layer 113.

The first through electrode 160, the second through electrode 170, and the third through electrode 180 may be disposed in a through hole passing through each insulating layer. For example, the first through electrode 160, the second through electrode 170, and the third through electrode 180 may be formed by filling the through holes with a conductive material.

The through holes may be formed by any one of mechanical, laser, and chemical processing methods. The through holes may be formed by mechanical processing methods such as milling, drilling, and routing. In addition, the through holes may use a UV or CO2 laser method. In addition, the first through hole may use a chemical processing method using a chemical agent including monosilane, ketones, etc.

When the through hole is formed, the through hole can be filled with any one metal material selected from copper (Cu), silver (Ag), tin (Sn), gold (Au), nickel (Ni), and palladium (Pd) to form a first through electrode 160, a second through electrode 170, and a third through electrode 180. At this time, the filling of the conductive material can utilize any one of electroless plating, electrolytic plating, screen printing, sputtering, evaporation, ink-jetting, and dispensing, or a combination thereof.

Meanwhile, the first through electrode 160 may be formed in multiple numbers while being spaced apart horizontally within the first insulating layer 111.

At this time, the first through electrode 160 may overlap with the first circuit layer 120 in a vertical direction. In addition, the first through electrode 160 may include a first-first through electrode 160a that overlaps with the bump part 121 of the first circuit layer 120 in the vertical direction. In addition, the first through electrode 160 may include a first-second through electrode 160b that overlaps with the pad 122 of the first circuit layer 120 in the vertical direction.

At this time, the first through electrode 160 is formed integrally with the first circuit layer 120. This is because the filling of the inside of the through hole passing through the first insulating layer 111 and a plating process for forming the circuit layer on the first insulating layer 111 are performed simultaneously.

Accordingly, the pad 122 may be formed integrally with the first-second through electrode 160b. Here, being formed integrally may mean that at least one metal layer constituting the pad 122 and at least one metal layer constituting the first-second through electrode are plating layers formed by a single plating process.

Furthermore, the bump part 121 may be formed integrally with the first-first through electrode 160a. For example, the second portion 121B corresponding to the bump portion of the bump part 121 is formed integrally with the first portion 121P corresponding to the pad portion of the bump part 121. In addition, the first portion 121P of the bump part 121 is formed integrally with the first-first through electrode 160a. Therefore, the second portion 121B of the bump part 121 is formed integrally with the first-first through electrode 160a.

At this time, in the comparative example, although the pads of the through electrode and the bump part are formed integrally with each other, the bumps of the through electrode and the bump part are separate metal layers formed through separate processes. Accordingly, the comparative example has a problem that the electrical and physical connectivity between them is deteriorated and the signal transmission loss is increased.

In contrast, the embodiment has a structure in which the first-first through electrode 160a, the first portion 121P of the bump part 121, and the second portion 121B of the bump part 121 are formed integrally with each other. Accordingly, the embodiment can improve the electrical and physical connectivity between the first-first through electrode 160a and the bump part 121. Accordingly, the embodiment can improve the physical reliability and electrical reliability of the circuit board.

The circuit board 100 of the embodiment includes a protective layer.

Specifically, a first protective layer 195 is disposed on the upper surface of the first insulating layer 111. The first protective layer 195 includes at least one opening. Specifically, the first protective layer 195 includes an opening that overlaps vertically with the bump part 121 of the first circuit layer 120. At this time, a width of the opening of the first protective layer 195 may be the same as a width of the bump part 121.

Here, in the comparative example, a width of the opening of the first protective layer was larger or smaller than a width of the bump part. This is because it is difficult to form the width of the opening of the first protective layer and the width of the bump part to be substantially the same due to a tolerance in an exposure and development processes of the first protective layer. Accordingly, in the comparative example, the width of the opening of the first protective layer was increased or the width of the bump part was increased in consideration of the tolerance. Accordingly, in the comparative example, there was a limit to reducing the pitch between a plurality of bump parts.

In contrast, in the embodiment, the first protective layer 195 is formed after the bump part 121 is formed to a certain thickness. Accordingly, the embodiment can make the width of the bump part 121 and the width of the opening of the first protective layer 195 substantially the same. Through this, the embodiment can further reduce the pitch between the plurality of bump parts. Accordingly, the embodiment can improve the circuit integration of the circuit board.

Meanwhile, the circuit board 100 can further include a second protective layer 195 disposed on the lower surface of the third insulating layer 113.

The first protective layer 195 and the second protective layer 195 can include an insulating material. The first protective layer 195 and the second protective layer 195 can include various materials that can be applied and then cured by heating to protect the surfaces of the insulating layer and the circuit layer.

The first protective layer 195 and the second protective layer 195 can be a solder resist layer including an organic polymer material. For example, the first protective layer 195 and the second protective layer 195 may include an epoxy acrylate series resin. In detail, the first protective layer 195 and the second protective layer 195 may include a resin, a curing agent, a photo initiator, a pigment, a solvent, a filler, an additive, an acrylic series monomer, etc. However, the embodiment is not limited thereto, and the first protective layer 195 and the second protective layer 195 may be any one of a photo solder resist layer, a cover-lay, and a polymer material.

The thickness of the first protective layer 195 and the second protective layer 195 may be 1 um to 20 um. The thickness of the first protective layer 195 and the second protective layer 195 may be 1 um to 15 um. For example, the thickness of the first protective layer 195 and the second protective layer 195 may be 5 μm to 20 μm. When the thickness of the first protective layer 195 and the second protective layer 195 exceeds 20 μm, the overall thickness of the circuit board and the semiconductor package may increase.

Meanwhile, although the circuit board is illustrated in the drawing as including the first protective layer 195 and the second protective layer 195, it is not limited thereto.

For example, at least one of the first protective layer 195 and the second protective layer 195 may be omitted.

Preferably, the first protective layer 195 may be omitted in the circuit board 100 of FIG. 2. Accordingly, the upper surface of the first insulating layer 111 and the upper surface and side surface of the first circuit layer 120 may be exposed to an outside of the circuit board 100. In addition, at least a part of the upper surface of the first insulating layer 111 and the upper surface and a side surface of the first circuit layer 120 may be covered by a molding layer in the semiconductor packaging process.

Meanwhile, although not shown in the drawing, a surface treatment layer may be disposed on the first circuit layer 120 of the circuit board 100. For example, a surface treatment layer may be disposed on the upper surface of at least one of the bump part 121 and the pad 122 of the first circuit layer 120. The surface treatment layer may be formed to prevent corrosion and oxidation of the circuit layer while increasing solderability.

The surface treatment layer may be an OSP (Organic Solderability Preservative) layer. Preferably, the surface treatment layer may be an organic layer formed of an organic material such as benzimidazole coated on the circuit layer.

Unlike this, the surface treatment layer may be a plating layer. For example, the surface treatment layer may include an electroless-plated gold (Au) plating layer. For example, the surface treatment layer may include an electroless plated nickel (Ni) plating layer, and an electroless plated gold (Au) plating layer on the nickel plating layer. For example, the surface treatment layer may include an electroless plated nickel (Ni) plating layer, an electroless plated palladium (Pd) plating layer on the nickel plating layer, and an electroless plated gold (Au) plating layer on the palladium plating layer.

Hereinafter, the circuit layers included in the circuit board of the embodiment will be described in more detail.

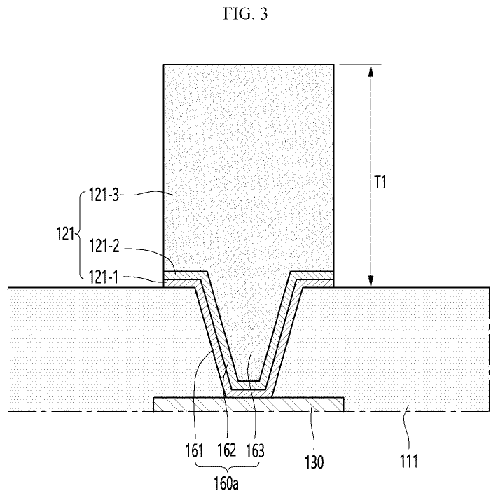

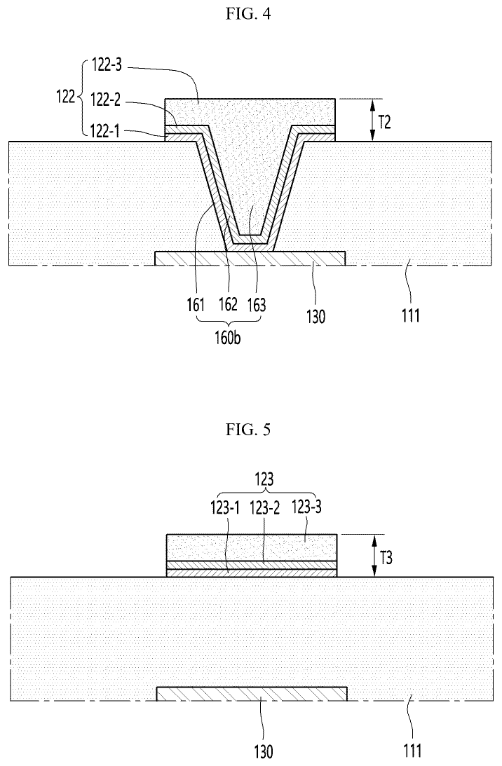

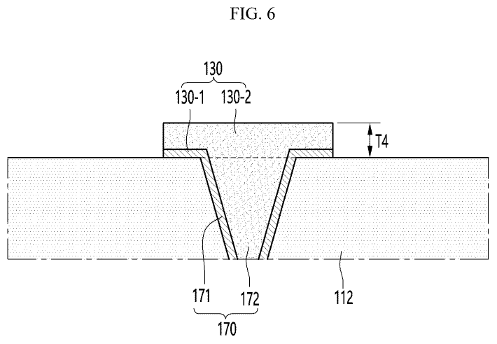

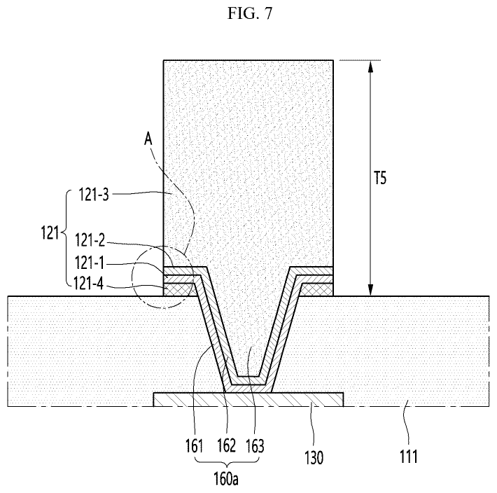

FIG. 3 is a cross-sectional view showing a layer structure of a bump part of a first circuit layer of a first embodiment, FIG. 4 is a cross-sectional view showing a layer structure of a pad of a first circuit layer of a first embodiment, FIG. 5 is a cross-sectional view showing a layer structure of a trace of a first circuit layer of a first embodiment, FIG. 6 is a cross-sectional view showing a layer structure of a second circuit layer of an embodiment, and FIG. 7 is a cross-sectional view showing a layer structure of a bump part of a first circuit layer of a second embodiment.

Referring again to FIG. 2 for a moment, the first circuit layer 120 includes a bump part 121, a pad 122, and a trace 123. In addition, the first circuit layer 120, the bump part 121, and the pad 122 have a same layer structure, and but at least one has a different thickness from at least one other.

On the other hand, the second circuit layer 130 has a different layer structure from the first circuit layer 120. For example, the second circuit layer 130 has a smaller number of layers than the first circuit layer 120. For example, the number of layers of the seed layer of the second circuit layer 130 is smaller than the number of layers of the seed layer of the first circuit layer 120.

Meanwhile, the first circuit layer 120 of the embodiment may have different layer structures depending on the manufacturing method. For example, when the first circuit layer 120 is manufactured by a SAP method, the first circuit layer 120 includes only the first to third metal layers 121-1, 121-2, and 121-3 that do not include a fourth metal layer 121-4 corresponding to a copper layer. In addition, when the first circuit layer 120 is manufactured by a MSAP method, the first circuit layer 120 may include first to fourth metal layers 121-1, 121-2, 121-3, and 121-4 including a copper layer.

Referring to FIG. 3, the circuit board 100 includes a first-first through electrode 160a passing through the first insulating layer 111 and a bump part 121 of the first circuit layer 120 disposed on the first-first through electrode 160a.

At this time, the first-first through electrode 160a and the bump part 121 are formed integrally.

The bump part 121 includes a plurality of metal layers. In addition, the first-first through electrode 160a also includes a plurality of metal layers corresponding to the plurality of metal layers of the bump part 121. In addition, each of the plurality of metal layers of the bump part 121 is formed integrally with a corresponding metal layer among the plurality of metal layers of the first-first through electrode 160a. Being formed integrally may mean that any one of the plurality of metal layers constituting the bump part 121 and any one of the plurality of metal layers constituting the first-first through electrode 160a are formed as one layer.

The bump part 121 includes a first metal layer 121-1. The first metal layer 121-1 is disposed on the upper surface of the first insulating layer 111 in the circuit board of the first embodiment.

The first metal layer 121-1 of the bump part 121 may be an electroless plating layer. For example, the first metal layer 121-1 of the bump part 121 may be a chemical copper plating layer.

For example, the first metal layer 121-1 of the bump part 121 can be formed by a chemical copper plating method that is performed in the order of a degreasing process, a soft corrosion process, a pre-catalyst treatment process, a catalyst treatment process, an activation process, an electroless plating process, and an anti-oxidation treatment process.

The first metal layer 121-1 of the bump part 121 can have a first thickness. The first thickness of the first metal layer 121-1 of the bump part 121 can satisfy a range of 0.5 um to 1.5 um. Preferably, the first thickness of the first metal layer 121-1 of the bump part 121 can satisfy a range of 0.7 um to 1.3 um. More preferably, the first thickness of the first metal layer 121-1 of the bump part 121 can satisfy a range of 0.8 um to 1.2 um. If the first thickness of the first metal layer 121-1 of the bump part 121 is less than 0.5 um, the first metal layer 121-1 may not function normally as a seed layer. If the first thickness of the first metal layer 121-1 of the bump part 121 is greater than 1.5 um, the reliability of the bump part 121 may deteriorate. For example, if the first thickness of the first metal layer 121-1 of the bump part 121 is greater than 1.5 um, a depth of the recess portion (or undercut) may increase in an etching process of the first metal layer 121-1 performed after the formation of the bump part 121. In addition, if the first thickness of the first metal layer 121-1 of the bump part 121 is greater than 1.5 um, an etching process time may increase. In addition, if the first thickness of the first metal layer 121-1 of the bump part 121 is greater than 1.5 um, deformation of the third metal layer 123 of the bump part 121 may occur during an etching process of the first metal layer 121-1.

The bump part 121 may include a second metal layer 121-2 disposed on the first metal layer 121-1. The second metal layer 121-2 of the bump part 121 may be an electrolytic plating layer. For example, the second metal layer 121-2 of the bump part 121 may be a first electrolytic plating layer formed by electrolytically plating the first metal layer 121-1 of the bump part 121 as a seed layer.

The second metal layer 121-2 of the bump part 121 may have a second thickness greater than the first thickness of the first metal layer 121-1 of the bump part 121. For example, the second thickness of the second metal layer 121-2 of the bump part 121 may be 1.3 times or more the first thickness of the first metal layer 121-1 of the bump part 121. For example, the second thickness of the second metal layer 121-2 of the bump part 121 may be 1.5 times or more the first thickness of the first metal layer 121-1 of the bump part 121. For example, the second thickness of the second metal layer 121-2 of the bump part 121 may be 2 times or more the first thickness of the first metal layer 121-1 of the bump part 121.

The second thickness of the second metal layer 121-2 of the bump part 121 can satisfy a range of 3 um to 5 um. For example, the second thickness of the second metal layer 121-2 of the bump part 121 can satisfy a range of 3.2 um to 4.8 um. For example, the second thickness of the second metal layer 121-2 of the bump part 121 can satisfy a range of 3.5 um to 4.5 um.

If the second thickness of the second metal layer 121-2 of the bump part 121 is less than 3 um, an effect exhibited by the formation of the second metal layer 121-2 may be insignificant. For example, the second metal layer 121-2 of the bump part 121 can have a function of reducing a depth of a recess portion in an etching process of the first metal layer 121-1 while improving the processability in a plating process of the bump part 121. For example, the second metal layer 121-2 of the bump part 121 can have a function of reducing the thickness deviation between a plurality of bump parts. In addition, if the second thickness of the second metal layer 121-2 of the bump part 121 is less than 3 um, the effect of the second metal layer 121-2 may be insignificant. If the second thickness of the second metal layer 121-2 of the bump part 121 exceeds 5 um, a process time in a process of etching the second metal layer 121-2 may increase.

The first metal layer 121-1 and the second metal layer 121-2 of the bump part 121 function as seed layers for forming the third metal layer 121-3 by electrolytic plating. Specifically, the first metal layer 121-1 functions as a seed layer for forming the second metal layer 121-2 by electrolytic plating. In addition, the first metal layer 121-1 and the second metal layer 121-2 function as seed layers for forming the third metal layer 121-3 by electrolytic plating.

That is, the bump part 121 includes a third metal layer 121-3 disposed on the second metal layer 121-2 of the bump part 121. The third metal layer 121-3 is an electrolytic plating layer formed by electrolytic plating the first metal layer 121-1 and the second metal layer 121-2 as a seed layer. For example, the third metal layer 121-3 of the bump part 121 may also be referred to as a second electrolytic plating layer of the bump part 121.

A third thickness of the third metal layer 121-3 of the bump part 121 may exceed 95 μm. For example, the third thickness of the third metal layer 121-3 of the bump part 121 may exceed 115 μm. The third thickness of the third metal layer 121-3 of the bump part 121 may exceed 135 um. The third thickness of the third metal layer 121-3 of the bump part 121 may exceed 155 um. The third thickness of the third metal layer 121-3 of the bump part 121 may exceed 195 um.

That is, the bump part 121 includes a first metal layer 121-1, a second metal layer 121-2, and a third metal layer 121-3. In addition, a thickness T1 of the bump part 121 including the first metal layer 121-1, the second metal layer 121-2, and the third metal layer 121-3 may satisfy a range of 100 um to 220 um. Preferably, the thickness T1 of the bump part 121 can satisfy a range of 110 um to 215 um. More preferably, the thickness T1 of the bump part 121 can satisfy a range of 115 um to 210 um.

If the thickness T1 of the bump part 121 is less than 100 um, an external substrate (e.g., a main board of an electronic device) may not be stably bonded onto the first bump part 121. For example, if the thickness T1 of the bump part 121 exceeds 220 um, the rigidity of the bump part 121 may be reduced, and thus, a reliability problem such as collapse in a state in which the external substrate is coupled may occur. In addition, if the thickness T1 of the bump part 121 exceeds 220 um, the thickness deviation between a plurality of bump parts may increase, and thus, a time for a polishing process may increase. In addition, if the thickness T1 of the bump part 121 exceeds 220 um, a thickness of the circuit board 100 and a thickness of the semiconductor package may increase.

In the embodiment, the bump part 121 includes a first metal layer 121-1, a second metal layer 121-2, and a third metal layer 121-3. In addition, the second metal layer 121-2 is a first electroplated layer in which the first metal layer 121-1 is electroplated as a seed layer, and the third metal layer 121-3 is a second electroplated layer in which the first metal layer 121-1 and the second metal layer 121-2 are electroplated as a seed layer.

Therefore, the embodiment can minimize the depth of the recess portion that occurs in the etching process of the seed layer that is performed after the formation of the circuit layer. That is, the second metal layer 121-2 may have a higher metal density than the first metal layer 121-1 as an electrolytic plating layer. Therefore, the second metal layer 121-2 may function as a barrier layer that minimizes the depth of a recess portion formed at a side surface of the first metal layer 121-1 during an etching process. Furthermore, the second metal layer 121-2 may function to prevent the third metal layer 121-3 from being deformed during an etching process. Therefore, the embodiment may minimize the depth of a recess portion formed at a lower side surface of the bump part 121 by further including the second metal layer 121-2. Therefore, the embodiment may improve the physical reliability and electrical reliability of the bump part 121.

In addition, the third metal layer 121-3 of the bump part 121 is electroplated not only with the first metal layer 121-1 but also with the second metal layer 121-2 as a seed layer. Accordingly, the embodiment can minimize the thickness deviation between the plurality of bump parts included in the circuit board 100.

Specifically, in the circuit board of the comparative example, the plating of the bump part is performed using only the chemical copper plating layer as a seed layer. At this time, the bump part has a thickness of 100 um or more. Accordingly, when plating a metal layer having a thickness of 100 um or more, it is difficult to perform a plating process having a uniform thickness over an entire region with only the chemical copper plating layer. Therefore, in the circuit board of the comparative example, the thickness deviation of each bump part exceeded 30% compared to the average value of the thickness of the plurality of bump parts. For example, when the average value was 100 um, the thickness of at least one bump part among the plurality of bump parts was less than 70 um or exceeded 130 um. Accordingly, the circuit board of the comparative example performs the plating process to have a thickness greater than a target thickness in order to match the thickness of each bump part. Accordingly, the comparative example has a problem in that a polishing process must be included to uniformize the thickness while finally adjusting the thickness of the bump part to the target thickness, and the polishing process time increases.

In contrast, the embodiment performs electrolytic plating of the third metal layer 121-3 of the bump part 121 using not only the first metal layer 121-1 of the bump part 121 but also the second metal layer 121-2 as a seed layer. Accordingly, the embodiment can minimize the thickness deviation between the plurality of bump parts. Accordingly, the embodiment can perform the plating process under a condition that the bump part 121 has a thickness corresponding to the target thickness. Accordingly, the embodiment can omit the polishing process or drastically shorten the polishing process time.

Specifically, the circuit board 100 of the embodiment includes a plurality of bump parts 121a and 121b spaced apart from each other in a horizontal direction. Then, the embodiment can adjust the deviation of the thickness of each bump part 121 a and 121 b to 20% or less based on the average value of the thickness of the plurality of bump parts 121a and 121b. For example, the embodiment can adjust the deviation of the thickness of each bump part 121 a and 121 b to 15% or less based on the average value of the thickness of the plurality of bump parts 121a and 121b. For example, the embodiment can adjust the deviation of the thickness of each bump part 121a and 121 b to 10% or less based on the average value of the thickness of the plurality of bump parts 121 a and 121b.

Meanwhile, the first through electrode 160 of the circuit board of the embodiment includes a first-first through electrode 160a that overlaps the bump part 121 in a vertical direction. In addition, the first-first through electrode 160a may have a layer structure corresponding to the bump part 121.

For example, the first-first through electrode 160a may include a first metal layer 161, a second metal layer 162, and a third metal layer 163 of the first-first through electrode 160a corresponding to the first metal layer 121-1, the second metal layer 121-2, and the third metal layer 121-3 of the bump part 121.

The first metal layer 161 of the first-first through electrode 160a may correspond to the first metal layer 121-1 of the bump part 121. In other words, the first metal layer 161 of the first-first through electrode 160a may be formed integrally with the first metal layer 121-1 of the bump part 121.

In addition, the second metal layer 162 of the first-first through electrode 160a may correspond to the second metal layer 121-2 of the bump part 121. In other words, the second metal layer 162 of the first-first through electrode 160a may be formed integrally with the second metal layer 121-2 of the bump part 121.

In addition, the third metal layer 163 of the first-first through electrode 160a may correspond to the third metal layer 121-3 of the bump part 121. In other words, the third metal layer 163 of the first-first through electrode 160a may be formed integrally with the third metal layer 121-3 of the bump part 121.

Accordingly, the bump part 121 of the embodiment may have a structure formed integrally with the first-first through electrode 160a of the first through electrode 160.

Meanwhile, referring to FIG. 4, the first circuit layer 120 includes a pad 122. At this time, a thickness T2 of the pad 122 is smaller than a thickness T1 of the bump part 121.

At this time, the pad 122 includes the first to third metal layers 122-1, 122-2, and 122-3.

In addition, the first and second metal layers 122-1 and 122-2 of the pad 122 correspond to the first metal layer 121-1 and the second metal layer 121-2 of the bump part 121.

At this time, the third metal layer 122-3 of the pad 122 is identical to the third metal layer 121-3 of the bump part 121 in that the first and second metal layers 122-1 and 122-2 of the pad 122 are electrolytically plated as a seed layer.

However, a thickness of the third metal layer 122-3 of the pad 122 is smaller than the thickness of the third metal layer 121-3 of the bump part 121. In other words, the thickness of the third metal layer 122-3 of the pad 122 can be determined based on an overall thickness T2 of the pad 122.

In addition, the circuit board 100 includes a first-second through electrode 160b that is vertically overlapped with the pad 122.

The first-second through electrode 160b may have a layer structure corresponding to the layer structure of the pad 122.

For example, the first-second through electrode 160b may include a first metal layer 161 of the first-second through electrode 160b corresponding to the first metal layer 122-1 of the pad 122. The first metal layer 161 of the first-second through electrode 160b may be formed integrally with the first metal layer 122-1 of the pad 122.

For example, the first-second through electrode 160b may include a second metal layer 162 of the first-second through electrode 160b corresponding to the second metal layer 122-2 of the pad 122. The second metal layer 162 of the first-second through electrode 160b may be formed integrally with the second metal layer 122-2 of the pad 122.

For example, the first-second through electrode 160b may include the third metal layer 163 of the first-second through electrode 160b corresponding to the third metal layer 122-3 of the pad 122. The third metal layer 163 of the first-second through electrode 160b may be formed integrally with the third metal layer 122-3 of the pad 122.

Meanwhile, referring to FIG. 5, a trace 123 of the first circuit layer 120 may include the first to third metal layers 123-1, 123-2, and 123-3.

At this time, the first to third metal layers 123-1, 123-2, and 123-3 of the trace 123 may correspond to the first to third metal layers 122-1, 122-2, and 122-3 of the pad 122. In addition, a thickness T3 of the trace 123 may correspond to the thickness T2 of the pad 122.

Accordingly, a specific description of the first to third metal layers 123-1, 123-2, and 123-3 of the trace 123 will be omitted.

Meanwhile, referring to FIG. 6, the second circuit layer 130 of the circuit board 100 may have a different layer structure from the first circuit layer 120. For example, the number of layers of the second circuit layer 130 may be different from the number of layers of the first circuit layer 120. For example, the number of layers of the metal layer of the second circuit layer 130 may be smaller than the number of layers of the metal layer of the first circuit layer 120.

Correspondingly, the second through electrode 170 passing through the second insulating layer 112 of the circuit board 100 may have a different layer structure from the first through electrode 160. For example, the second through electrode 170 may include a metal layer having a smaller number of layers than the number of layers of the metal layer included in the first through electrode 160.

For example, the second circuit layer 130 includes a first metal layer 130-1 corresponding to the first metal layer (122-1 or 123-1) of the pad 122 or trace 123 of the first circuit layer 120. In addition, the second circuit layer 130 includes a third metal layer 130-2 corresponding to the third metal layer (122-3 or 123-3) of the pad 122 or trace 123 of the first circuit layer 120. In other words, the second circuit layer 130 may have a structure that does not include the second metal layer (122-2 or 123-2) of the pad 122 or trace 123 compared to the pad 122 or trace 123 of the first circuit layer 120.

In addition, the second through electrode 170 includes a first metal layer 171 corresponding to the first metal layer 160-1 of the first-first through electrode 160a or the first-second through electrode 160b. In addition, the second through electrode 170 includes a second metal layer 172 corresponding to the third metal layer 160-3 of the first-first through electrode 160a or the first-second through electrode 160b. In other words, the second through electrode 170 may have a structure that does not include the second metal layer 160-2 of the first-first through electrode 160a or the first-second through electrode 160b, compared to the first-first through electrode 160a or the first-second through electrode 160b.

Meanwhile, referring to FIG. 7, the circuit board 100 of the embodiment may be manufactured through the MSAP process.

Specifically, the first circuit layer 120 may further include a fourth metal layer compared to FIGS. 3 to 5. In other words, each of the bump part 121, the pad 122, and the trace 123 of the first circuit layer 120 may further include a fourth metal layer disposed between an upper surface of the first insulating layer 111 and the first metal layer. In contrast, the first through electrode 160 may include first to third metal layers 161, 162, and 163 as described in FIGS. 3 to 5.

At this time, the bump part 121, pad 122, and trace 123 of the first circuit layer 120 each include the same fourth metal layer. Accordingly, the following description will focus on the fourth metal layer 121-4 of the bump part 121.

The bump part 121 of the first circuit layer 120 further includes a fourth metal layer 121-4. The fourth metal layer 121-4 is disposed between the first metal layer 121-1 of the bump part 121 and the upper surface of the first insulating layer 111. The fourth metal layer 121-4 may be a copper foil layer. Specifically, the fourth metal layer 121-4 may be a copper foil attached to the upper surface of the first insulating layer 111 in a process of laminating the first insulating layer 111.

In addition, the circuit board 100 of the second embodiment is manufactured using the MSAP process, and accordingly, the circuit layer formation process is performed without removing the fourth metal layer 121-4, which is a copper layer disposed on the upper surface of the first insulating layer 111.

The fourth metal layer 121-4 may have a fourth thickness. For example, the fourth thickness of the fourth metal layer 121-4 may satisfy a range of 0.8 um to 2 um. The fourth thickness of the fourth metal layer 121-4 may satisfy a range of 1.0 um to 1.8 um. The fourth thickness of the fourth metal layer 121-4 may satisfy a range of 1.2 um to 1.6 um. If the fourth thickness of the fourth metal layer 121-4 is less than 0.8 um, reliability problems such as a decrease in flatness in a process of laminating the first insulating layer 111 may occur. If the fourth thickness of the fourth metal layer 121-4 exceeds 2 um, the processability in the process of etching the fourth metal layer 121-4 (for example, a process of etching the seed layer or a process of forming the through hole) may be deteriorated.

Accordingly, a thickness T5 of the bump part 121 of the second embodiment may be greater than the thickness T1 of the bump part 121 of the first embodiment by the fourth thickness of the fourth metal layer 121-4.

Hereinafter, a recess portion formed at a lower region of the bump part 121 of the embodiment will be described.

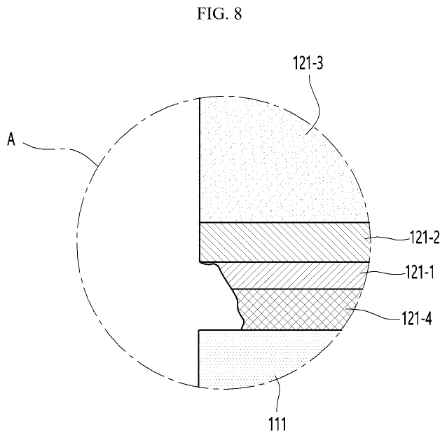

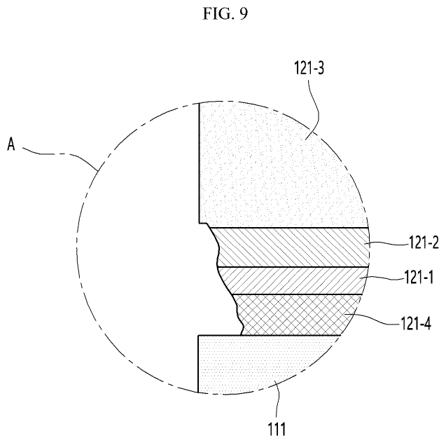

FIG. 8 is an enlarged view of area A of FIG. 7 according to the first embodiment, and FIG. 9 is an enlarged view of area A of FIG. 7 according to the second embodiment.

Referring to FIGS. 8 and 9, the first circuit layer 120 of the embodiment may include a recess portion formed in a lower region adjacent to the upper surface of the first insulating layer 111. The recess portion may also be referred to as an undercut. The recess portion may be formed in the lower regions of the bump part 121, the pad 122, and the trace 123 of the first circuit layer 120, respectively.

Specifically, referring to FIG. 7, the recess portion may be formed in the first metal layer and the fourth metal layer of each of the bump part 121, the pad 122, and the trace 123.

Differently, referring to FIG. 8, the recess portion may be formed in the first, second, and fourth metal layers.

Hereinafter, the recess portion formed in the bump part 121 will be described. In addition, the recess portion may also be formed in the pad 122 and trace 123 of the first circuit layer 120 corresponding to the recess portion formed in the bump part 121.

At this time, there is no interface between the bump part 121 and the first-first through electrode 160a. That is, an absence of an interface may mean that the bump part 121 and the first-first through electrode 160a are formed integrally with each other.

Referring to FIG. 7, the recess portion in the bump part 121 may be formed in the first metal layer 121-1 and the fourth metal layer 121-4 of the bump part 121. In addition, when the bump part 121 is formed by the SAP process, the recess portion of the bump part 121 may be formed only in the first metal layer 121-1 of the bump part 121.

Accordingly, the bump part 121 may include a portion whose width changes in a thickness direction.

For example, the bump part 121 may have a width in a region where the first metal layer 121-1 is disposed smaller than a width in a region where the third metal layer 121-3 is disposed. In addition, the bump part 121 may have a width in a region where the fourth metal layer 121-4 is disposed smaller than the width in a region where the third metal layer 121-3 is disposed.

In addition, the bump part 121 may have a width in a region where the first metal layer 121-1 is disposed smaller than the width in a region where the second metal layer 121-2 is disposed. In addition, the bump part 121 may have a width in a region where the second metal layer 121-2 is disposed larger than the width in a region where the fourth metal layer 121-4 is disposed.

In addition, the bump part 121 may have a width in a region where the second metal layer 121-2 is disposed, which may be the same as the width in a region where the third metal layer 121-3 is disposed.

At this time, the embodiment additionally forms a second metal layer 121-2 on the first metal layer 121-1, and forms a third metal layer 121-3 using the formed second metal layer 121-2 as an additional seed layer. In addition, the embodiment can prevent the etching of the first metal layer 121-1 from proceeding excessively by the second metal layer 121-2 in a process of etching the seed layer after forming the third metal layer 121-3. Accordingly, the embodiment can minimize the depth of the recess portion (specifically, the width of the recess portion in the horizontal direction).

Also, referring to FIG. 8, the recess portion in the bump part 121 may be formed in the first metal layer 121-1, the second metal layer 121-2, and the fourth metal layer 121-4 of the bump part 121. In addition, when the bump part 121 is formed by the SAP process, the recess portion of the bump part 121 may be formed in the first metal layer 121-1 and the second metal layer 121-2 of the bump part 121.

Accordingly, the bump part 121 may include a portion whose width changes in the thickness direction.

For example, the width of the bump part 121 in the region where the first metal layer 121-1 is disposed may be smaller than the width in the region where the third metal layer 121-3 is disposed. In addition, the bump part 121 may have a width in a region where the fourth metal layer 121-4 is disposed smaller than the width in a region where the third metal layer 121-3 is disposed. In addition, the bump part 121 may have a width in a region where the second metal layer 121-2 is disposed smaller than the width in a region where the third metal layer 121-3 is disposed.

At this time, in the embodiment, a part of the recess portion may also be formed in the second metal layer 121-2. However, the depth of the recess portion in the second metal layer 121-2 is smaller than the depth of the recess portion in the first metal layer 121-1.

For example, at least a part of a region where the second metal layer 121-2 is disposed has a width larger than a region where the first metal layer 121-1 is disposed. In addition, in the embodiment, although a recess portion can be formed in the second metal layer 121-2 of the bump part 121, the depth of the recess portion formed at second metal layer 121-2 can be minimized, and further, the depth of the recess portion formed at the first metal layer 121-1 and the fourth metal layer 121-4 by the second metal layer 121-2 can also be minimized.

The circuit board of the embodiment comprises an insulating layer, a through electrode passing through the insulating layer, and a first circuit layer disposed on the insulating layer. At this time, the first circuit layer includes a bump part. The bump part is provided to pass through a protective layer disposed on the insulating layer and protrude on the protective layer.

The bump part includes a first portion disposed on the insulating layer and the through electrode, and a second portion on the first portion. There is no interface between the first portion and the second portion of the bump part. In other words, the first portion and the second portion are formed integrally with each other. Furthermore, the through electrode is formed integrally with the first portion and the second portion of the bump part. In other words, there is no interface between the through electrode and the bump part.

Therefore, the bump part of the embodiment does not have an additional layer disposed between the first portion and the second portion. Specifically, the bump part does not have a seed layer between the first portion and the second portion. Through this, the embodiment can improve physical connectivity and electrical connectivity between the first portion and the second portion of the bump part. Furthermore, the bump part of the embodiment is formed integrally with the through electrode, and thus the electrical and physical reliability can be further improved.

At this time, in a comparative example, the pad part and the bump part are formed through separate plating processes separated from each other. Therefore, the comparative example has problems in that the electrical and physical connectivity between them is reduced and the signal transmission loss is increased. Furthermore, the comparative example has a structure in which a seed layer is additionally disposed between the pad part and the bump part, and thus overall reliability of the bump part is reduced due to physical reliability problem of the seed layer.

In contrast, the embodiment has a structure in which the through electrode, the first portion of the bump part, and the second portion of the bump part are formed integrally with each other. Accordingly, the embodiment can improve the electrical and physical connectivity between the through electrode and the bump part. Accordingly, the embodiment can improve the physical reliability and electrical reliability of the circuit board.

In addition, the bump part of the embodiment includes a first metal layer, a second metal layer, and a third metal layer. In addition, the second metal layer is a first electroplated layer in which the first metal layer is electroplated as a seed layer, and the third metal layer is a second electroplated layer in which the first metal layer and the second metal layer are electroplated as seed layers.

Therefore, the embodiment can minimize a depth of a recess portion that occurs in an etching process of the seed layer that is performed after a formation of the circuit layer. That is, the second metal layer can have a higher strength than the first metal layer as an electroplated layer. Therefore, the second metal layer can function as a barrier layer that minimizes the depth of the recess portion that occurs at a side surface of the first metal layer in the etching process. Furthermore, the second metal layer can function to prevent the third metal layer from being deformed in the etching process. Therefore, the embodiment can minimize a depth of a recess portion formed at a lower side surface of the bump part by the bump part further including the second metal layer. Therefore, the embodiment can improve the physical reliability and electrical reliability of the bump part.

In addition, the third metal layer of the bump part is electroplated not only on the first metal layer but also on the second metal layer as a seed layer. Accordingly, the embodiment can minimize a thickness deviation between the plurality of bump parts included in the circuit board.

Specifically, in the circuit board of the comparative example, the plating of the bump part is performed using only the chemical copper plating layer as the seed layer. At this time, the bump part has a thickness of 100 um or more. Accordingly, when plating a metal layer having a thickness of 100 um or more, it is difficult to perform a plating process having a uniform thickness over an entire region with only the chemical copper plating layer. Therefore, in the circuit board of the comparative example, the thickness deviation of each bump part exceeded 30% compared to an average value of a thickness of the plurality of bump parts. For example, when the average value was 100 um, the thickness of at least one bump part among the plurality of bump parts was less than 70 um or exceeded 130 um. Accordingly, in the circuit board of the comparative example, the plating process is performed so that a thickness of each bump part is greater than a target thickness in order to match the thickness of each bump part. Accordingly, the comparative example had a problem that a polishing process must be included to uniformize the thickness while finally adjusting the thickness of the bump part to the target thickness, and the polishing process time increases.

In contrast, the embodiment performs electrolytic plating of the third metal layer of the bump part using not only the first metal layer of the bump part but also the second metal layer as a seed layer. Accordingly, the embodiment can minimize the thickness deviation between a plurality of bump parts. Accordingly, the embodiment can perform a plating process under a condition that the bump part has a thickness corresponding to a target thickness. Accordingly, the embodiment can omit the polishing process or drastically shorten the polishing process time.

Specifically, in the circuit board of the comparative example, the plating of the bump part is performed using only the chemical copper plating layer as the seed layer. At this time, the bump part has a thickness of 100 um or more. Accordingly, when plating a metal layer having a thickness of 100 um or more, it is difficult to perform a plating process having a uniform thickness over an entire region with only the chemical copper plating layer. Therefore, in the circuit board of the comparative example, the thickness deviation of each bump part exceeded 30% compared to an average value of a thickness of the plurality of bump parts. For example, when the average value was 100 um, the thickness of at least one bump part among the plurality of bump parts was less than 70 um or exceeded 130 um. Accordingly, in the circuit board of the comparative example, the plating process is performed so that a thickness of each bump part is greater than a target thickness in order to match the thickness of each bump part. Accordingly, the comparative example had a problem that a polishing process must be included to uniformize the thickness while finally adjusting the thickness of the bump part to the target thickness, and the polishing process time increases.

In contrast, the embodiment performs electrolytic plating of the third metal layer of the bump part using not only the first metal layer of the bump part but also the second metal layer as a seed layer. Accordingly, the embodiment can minimize the thickness deviation between a plurality of bump parts. Accordingly, the embodiment can perform a plating process under a condition that the bump part has a thickness corresponding to a target thickness. Accordingly, the embodiment can omit the polishing process or drastically shorten the polishing process time.

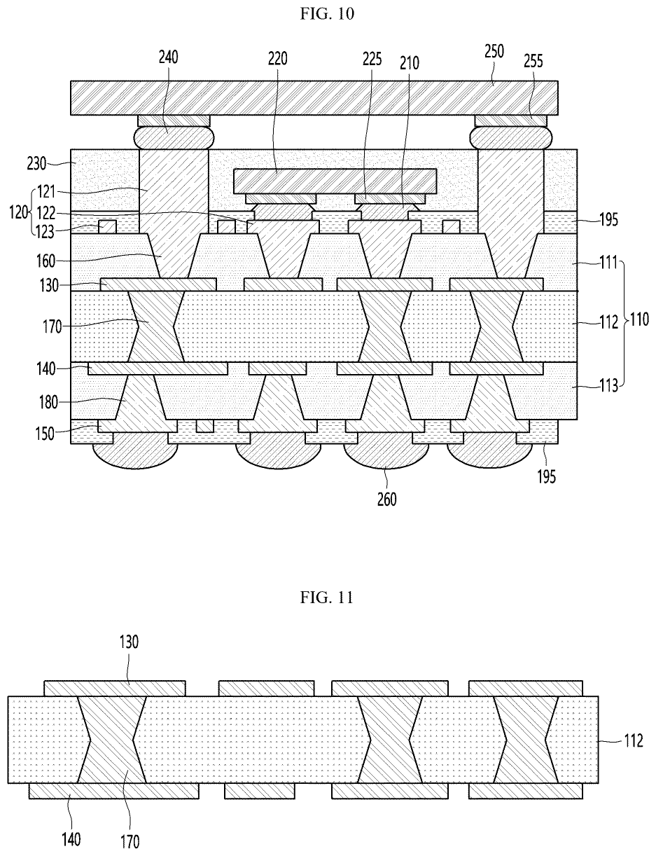

FIG. 10 is a view showing a semiconductor package according to an embodiment.

Referring to FIG. 10, the semiconductor package of the embodiment may have a structure in which a plurality of chips and an external substrate are disposed on the circuit board of FIG. 2.

To this end, the circuit board includes a bump part 121 and a pad 122 of a first circuit layer 120 In addition, the semiconductor package may include a first adhesive part 210 disposed on the pad 122 of the circuit board. In addition, the semiconductor package may include a second adhesive part 240 disposed on the bump part 121.

The first adhesive part 210 and the second adhesive part 240 may have the same shape, or may have different shapes.

For example, the first adhesive part 210 and the second adhesive part 240 may have a hexahedral shape. For example, cross-sections of the first adhesive portion 210 and the second adhesive portion 240 may include a square shape. The cross-sections of the first adhesive portion 210 and the second adhesive portion 240 may include a rectangular or square shape. For example, the first adhesive portion 210 and the second adhesive portion 240 may include a spherical shape. For example, the cross-sections of the first adhesive portion 210 and the second adhesive portion 240 may include a circular shape or a semicircular shape. For example, the cross-sections of the first adhesive portion 210 and the second adhesive portion 240 may include a partially or entirely rounded shape. The cross-sectional shapes of the first adhesive portion 210 and the second adhesive portion 240 may be flat on one side and curved on the other side. The first adhesive portion 210 and the second adhesive portion 240 may be solder balls, but are not limited thereto.

The embodiment may include a chip 220 disposed on a first adhesive portion 210. The chip 220 may be a first processor chip. For example, the chip 220 may be an application processor (AP) chip among a central processor (e.g., a CPU), a graphic processor (e.g., a GPU), a digital signal processor, an encryption processor, a microprocessor, and a microcontroller. A terminal 225 of the chip 220 may be electrically connected to a pad 122 through the first adhesive portion 210.

In addition, the embodiment may include an external substrate 250 coupled to a second adhesive portion 240. The external substrate 250 may include a terminal portion 255 electrically connected to the second adhesive portion 240 on a lower surface.

The external substrate 250 may be a main board. For example, the external substrate 250 may be a motherboard of an electronic device.

Alternatively, the external substrate 250 may be an interposer. For example, the external substrate 250 may be an interposer connecting the semiconductor package of the embodiment and another package (e.g., a memory package).

Alternatively, the external substrate 250 may be a memory substrate or a memory package on which a memory chip is mounted.

The semiconductor package may include a molding layer 230. The molding layer 230 may be disposed to cover the chip 220 and the bump part 121.

If the first protective layer 195 is omitted from the circuit board, the molding layer 230 may be disposed to cover the devices disposed on an upper side of the circuit board.

The molding layer 230 may be an EMC (Epoxy Mold Compound) formed to protect the mounted chip 220, but is not limited thereto.

At this time, the molding layer 230 may have a low dielectric constant to enhance heat dissipation characteristics. For example, the dielectric constant (Dk) of the molding layer 230 may be 0.2 to 10. For example, the dielectric constant (Dk) of the molding layer 230 may be 0.5 to 8. For example, the dielectric constant (Dk) of the molding layer 230 may be 0.8 to 5. Accordingly, the embodiment allows the molding layer 230 to have a low dielectric constant, thereby improving the heat dissipation characteristics of the heat generated from the chip 220.

Meanwhile, the semiconductor package may include a third adhesive part 260 disposed at a lowermost side of the circuit board. The third adhesive part 260 may be disposed on the lower surface of the fourth circuit layer 150 exposed through the opening of the second protective layer 195

Hereinafter, a method for manufacturing a circuit board according to the embodiment will be described.

FIGS. 11 to 22 are cross-sectional views showing the manufacturing method of the circuit board illustrated in FIG. 2 in order of processes.

Referring to FIG. 11, the embodiment can proceed with a process of manufacturing an inner layer of the circuit board 100. To this end, the embodiment prepares the second insulating layer 112. Then, the embodiment forms a through hole in the second insulating layer 112. Thereafter, the embodiment can proceed with a process of forming the second circuit layer 130 disposed on the upper surface of the second insulating layer 112 and the third circuit layer 140 disposed on the lower surface of the second insulating layer 112, together with the second through electrode 170 filling the through hole of the second insulating layer 112.

Meanwhile, if the circuit board 100 of the embodiment is not a core board, a process of manufacturing the inner layer can be performed using a carrier board.

In addition, if the circuit board 100 has a multilayer structure of four or more layers, a process of manufacturing the inner layer can be performed repeatedly multiple times.

Next, referring to FIG. 12, the embodiment can proceed with a process of manufacturing an outer layer on the manufactured inner layer.

To this end, the embodiment can proceed with a process of laminating a first insulating layer 111 on a second insulating layer 112. At this time, the first insulating layer 111 can have a structure in which a copper layer M1 is laminated. In addition, the copper layer M1 can be removed and disappear in the SAP process, and can form a part of the first circuit layer 120 in the MSAP process.

In response, the embodiment can proceed with a process of laminating a third insulating layer 113 under the second insulating layer 112. At this time, the embodiment can have a structure in which a copper layer M2 is laminated under the third insulating layer 113. In addition, the copper layer M2 can be removed and disappear in the SAP process, and can form a part of the fourth circuit layer 150 in the MSAP process.

Next, referring to FIG. 13, the embodiment may perform a process of forming a through hole by processing the first insulating layer 111 and the third insulating layer 113. For example, the embodiment may perform a process of forming a first through hole VH1 by processing the first insulating layer 111 and the copper layer M1.

In addition, the embodiment may perform a process of forming a second through hole VH2 by processing the third insulating layer 113 and the copper layer M2.

Meanwhile, the embodiment may perform a process of forming a first circuit layer 120 and a first through electrode 160 in the first insulating layer 111, and a process of forming a fourth circuit layer 150 and a third through electrode 180 in the third insulating layer 113.

Hereinafter, a manufacturing process will be described based on a manufacturing process of the first circuit layer 120 and the first through electrode 160 formed in the first insulating layer 111. In addition, the process of forming the fourth circuit layer 150 and the third through electrode 180 in the third insulating layer 113 may be performed correspondingly.

Referring to FIG. 14, the embodiment may perform a process of forming an electroless plating layer M2 on the inner wall of the copper layer M1 and the first through hole VH1 after the first through hole VH1 is formed. At this time, the electroless plating layer M2 may mean a chemical copper plating layer.

The electroless plating layer M2 may also be disposed on the upper surface of the second circuit layer 120 that vertically overlaps the first through hole VH1. The electroless plating layer M2 constitutes the first metal layer of each of the bump part 121, pad 122, and trace 123 of the first circuit layer 120 in the circuit board.

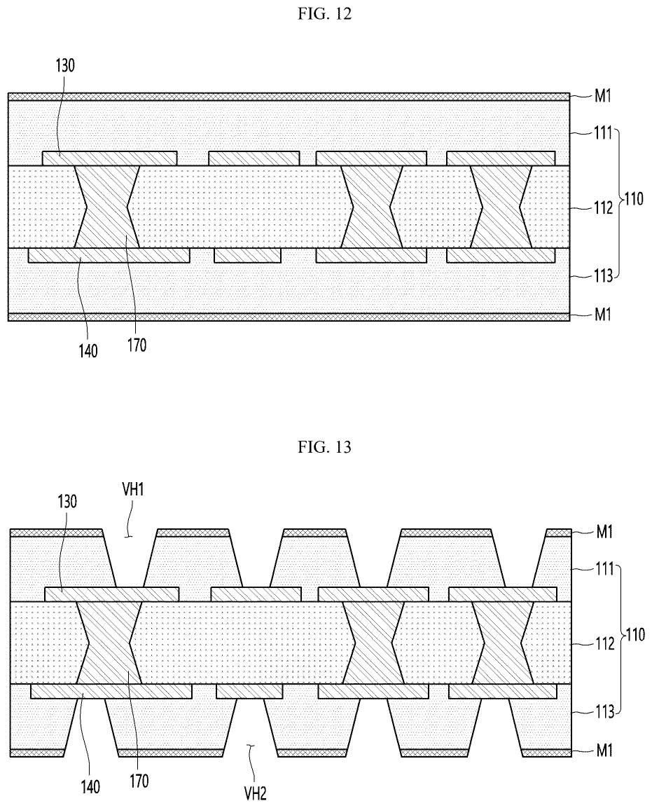

Referring to FIG. 15, the embodiment may perform a process of forming a first electrolytic plating layer M3 on the electroless plating layer M2. The first electrolytic plating layer M3 can be formed by performing primary electrolytic plating using the electroless plating layer M2 as a seed layer. In addition, the first electrolytic plating layer M3 constitutes the second metal layer of each of the bump part 121, pad 122, and trace 123 of the first circuit layer 120 in the circuit board. The first electrolytic plating layer M3 can be formed to correspond to a profile of a surface of the electroless plating layer M2.

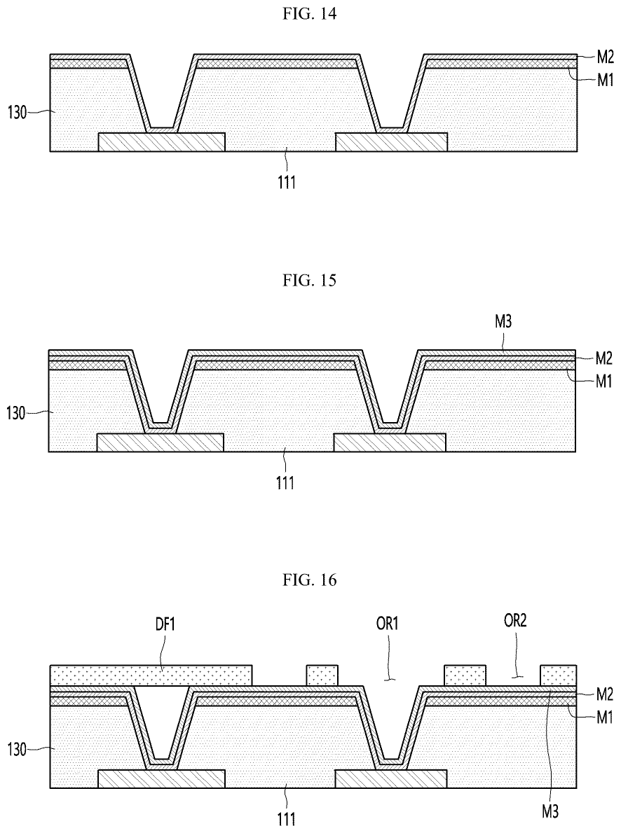

Referring to FIG. 16, the embodiment can perform a process of forming a first mask DF1 on the first electrolytic plating layer M3. At this time, the first mask DF1 includes a first open region OR1 and a second open region OR2. Preferably, the first mask DF1 may be formed with a first open region OR1 corresponding to a region where the pad 122 of the first circuit layer 120 and the first through electrode 160 are to be disposed among the upper areas of the first electrolytic plating layer M3. In addition, the first mask DF1 may be formed with a second open area OR2 corresponding to an area where the trace 123 of the first circuit layer 120 is to be disposed among the upper areas of the first electrolytic plating layer M3. At this time, the first mask DF1 is disposed to cover an area where the bump part 121 is to be disposed among the upper areas of the first electrolytic plating layer M3.

Referring to FIG. 17, the embodiment performs a process of forming a second electrolytic plating layer M4 by performing electrolytic plating on the electroless plating layer M2 and the first electrolytic plating layer M3 as a seed layer. Accordingly, a second electrolytic plating layer M4 can be formed corresponding to the first open area OR1 and the second open area OR2 of the first mask DF1. The second electrolytic plating layer M4 can constitute the third metal layer of the first-second through electrode 160b of the first through electrode 160, the pad 122 of the first circuit layer 120, and the trace 123.

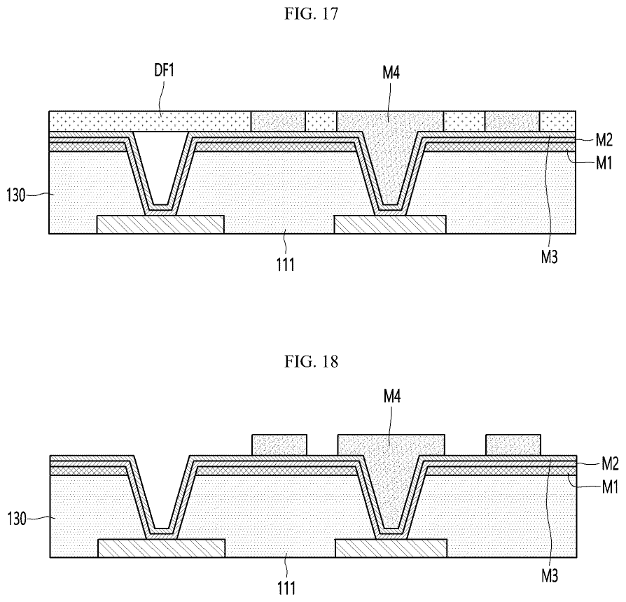

Next, referring to FIG. 18, the embodiment can perform a process of removing the first mask DF1 disposed on the first electrolytic plating layer M3.

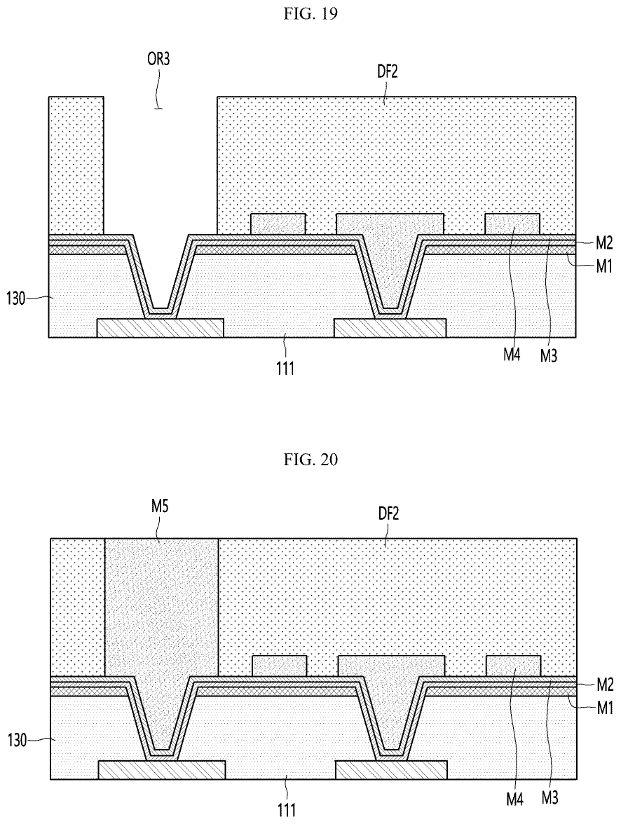

Next, referring to FIG. 19, the embodiment can perform a process of forming a second mask DF2 on the first electrolytic plating layer M3 and the second electrolytic plating layer M4. The second mask DF2 can include a third open region OR3. The third open region OR3 may be formed corresponding to a region where the first-first through electrode 160a and the bump part 121 of the first through electrode 160 are to be disposed among an upper region of the first electrolytic plating layer M3.

Next, referring to FIG. 20, the embodiment may perform electrolytic plating on the electroless plating layer M2 and the first electrolytic plating layer M3 as seed layers to form a third electrolytic plating layer M5 that fills the third open region OR3 of the second mask DF2. At this time, the third electrolytic plating layer M5 may constitute the third metal layer of each of the first-first through electrode 160a and the bump part 121.

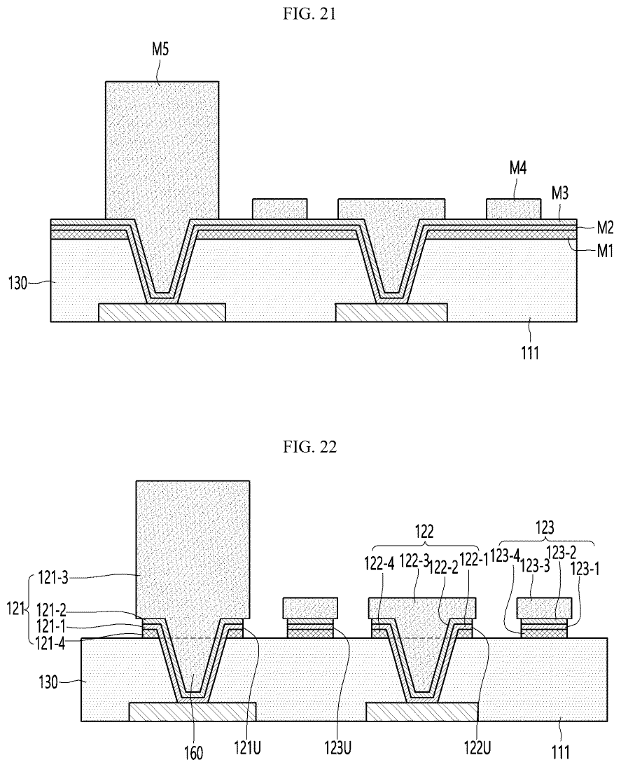

Next, referring to FIG. 21, the embodiment may perform a process of removing the second mask DF2.

Next, referring to FIG. 22, the embodiment can perform an etching process to remove the copper layer M1, the electroless plating layer M2, and the first electrolytic plating layer M3 in a region that does not vertically overlap the second electrolytic plating layer M4 and the third electrolytic plating layer M5.

Through this, the embodiment can form a first circuit layer 120 including a bump part 121, a pad 122, and a trace 123 formed integrally with the first through electrode, while including the first to fourth metal layers, respectively. At this time, in the etching process, a first recess portion 121U can be formed at a side surface of a lower region of the bump part 121. In addition, a second recess portion 122U can be formed at a side surface of a lower region of the pad 122 in the etching process. Additionally, a third recess portion 123U may be formed at a side surface of a lower region of the trace 123 in the etching process.

The characteristics, structures and effects described in the embodiments above are included in at least one embodiment but are not limited to one embodiment. Furthermore, the characteristic, structure, and effect illustrated in each embodiment may be combined or modified for other embodiments by a person skilled in the art. Thus, it would be construed that contents related to such a combination and such a modification are included in the scope of the present invention.

Embodiments are mostly described above. However, they are only examples and do not limit the present invention. A person skilled in the art may appreciate that several variations and applications not presented above may be made without departing from the essential characteristic of embodiments. For example, each component particularly represented in the embodiments may be varied. In addition, it should be construed that differences related to such a variation and such an application are included in the scope of the present invention defined in the following claims.

1. A circuit board package comprising:
an insulating layer; and
a circuit layer disposed on the insulating layer;
wherein the circuit layer includes:
a first metal layer disposed on the insulating layer;
a second metal layer disposed on the first metal layer; and
a third metal layer disposed on the second metal layer,
wherein a width of the circuit layer in a horizontal direction in the first metal layer, a width of the circuit layer in the horizontal direction in the second metal layer, and a width of the circuit layer in the horizontal direction in the third metal layer are different from each other.

2. The circuit board of claim 1, wherein the width of the circuit layer in the horizontal direction in the first metal layer is smaller than the width of the circuit layer in the horizontal direction in the second metal layer and the width of the circuit layer in the horizontal direction in the third metal layer, and
wherein the width of the circuit layer in the horizontal direction in the third metal layer is greater than the width of the circuit layer in the horizontal direction in the first metal layer and the width of the circuit layer in the horizontal direction in the second metal layer.

3-10. (canceled)

11. The circuit board of claim 1, wherein the circuit layer includes a first circuit pattern and a second circuit pattern that are disposed on the insulating layer and spaced apart along the horizontal direction, and
wherein a thickness of the first circuit pattern and a thickness of the second circuit pattern are different from each other.

12. The circuit board of claim 11, comprising:
a protective layer arranged on the insulating layer,
wherein the protective layer includes a first through hole that overlaps the first circuit pattern along a vertical direction, and a second through hole that overlaps the second circuit pattern along the vertical direction.

13. The circuit board of claim 12, wherein the thickness of the first circuit pattern is greater than the thickness of the second circuit pattern, and
wherein a thickness of the protective layer is less than the thickness of the first circuit pattern and greater than the thickness of the second circuit pattern.

14. The circuit board of claim 13, wherein a width of the first through hole and a width of the third metal layer of the first circuit pattern are same, and
wherein a width of the second through hole is greater than a width of the third metal layer of the second circuit pattern.

15. The circuit board of claim 14, wherein a thickness of the first metal layer of the first circuit pattern and a thickness of the first metal layer of the second circuit pattern are same, and
wherein a thickness of the second metal layer of the first circuit pattern and a thickness of the second metal layer of the second circuit pattern are same, and
wherein a thickness of the third metal layer of the first circuit pattern is greater than a thickness of the third metal layer of the second circuit pattern.

16. The circuit board of claim 15, wherein the circuit layer includes a third circuit pattern spaced apart from the first circuit pattern and the second circuit pattern along the horizontal direction, and
wherein the protective layer is provided to cover an upper surface and a side surface of the third circuit pattern.

17. The circuit board of claim 1, comprising:
a through electrode passing through at least a portion of the insulating layer along a vertical direction, and
wherein the through electrode and the circuit layer are integrally formed.

18. The circuit board of claim 17, wherein the through electrode has a slope whose width increases in the horizontal direction toward the circuit layer,
wherein an upper surface of the through electrode contacts a lower surface of the circuit layer, and
wherein a width of the upper surface of the through electrode is smaller than a width of the lower surface of the circuit layer.

19. The circuit board of claim 1, wherein thicknesses of each of the first to third metal layers in the vertical direction are different from each other.

20. The circuit board of claim 19, the thickness of the third metal layer in the vertical direction is greater than the thickness of the first metal layer and the thickness of the second metal layer in the vertical direction, and
wherein the thickness of the first metal layer in the vertical direction is smaller than the thickness of the second metal layer and the thickness of the third metal layer in the vertical direction.

21. The circuit board of claim 19, wherein the circuit layer includes a fourth metal layer disposed between the insulating layer and the first metal layer, and
wherein a width of the circuit layer in the horizontal direction in the fourth metal layer is different from a width of the circuit layer in the horizontal direction in each of the first to third metal layers.

22. The circuit board of claim 21, wherein the width of the circuit layer in the horizontal direction in the fourth metal layer is smaller than the width of the circuit layer in the horizontal direction in each of the first to third metal layers.

23. The circuit board of claim 21, wherein a thickness of the fourth metal layer in the vertical direction is smaller than the thickness of the second metal layer and the thickness of the third metal layer in the vertical direction.

24. The circuit board of claim 13, comprising:
a semiconductor chip disposed on the second circuit pattern.

25. The circuit board of claim 24, comprising:
a buried insulating layer disposed on the protective layer and embedding the semiconductor chip.

26. The circuit board of claim 25, wherein the first circuit pattern passes through the buried insulating layer along the vertical direction.
